(19) United States
(12) Patent Application Publication
(10) Pub. No.: US 2025/0098513 A1
(43) Pub. Date: Mar. 20, 2025

(54) STRETCHABLE LIGHT EMITTING MIXED COMPOSITION, STRETCHABLE LIGHT EMITTING MIXED FILM PREPARED USING THE SAME, AND A STRETCHABLE POLYMER LIGHT EMITTING DIODE DEVICE COMPRISING THE SAME

(71) Applicant: UNIVERSITY-INDUSTRY COOPERATION GROUP OF KYUNG HEE UNIVERSITY, Yongin-si (KR)

(72) Inventors: Jin Young OH, Anyang-si (KR); Seong Jun KANG, Seoul (KR); Min Woo JEONG, Gwangmyeong-si (KR); Jin Hyun MA, Yongin-si (KR)

(73) Assignee: UNIVERSITY-INDUSTRY COOPERATION GROUP OF KYUNG HEE UNIVERSITY, Yongin-si (KR)

(21) Appl. No.: 18/635,368

(22) Filed: Apr. 15, 2024

(30) Foreign Application Priority Data
Sep. 19, 2023 (KR) 10-2023-0125102

(51) Int. Cl. H10K 77/10; C08L 25/08; C08L 65/00; C09K 11/06; H10K 102/00

(52) U.S. Cl. CPC H10K 77/111; C08L 25/08; C08L 65/00; C09K 11/06; C08L 2203/20; C09K 2211/1416; H10K 2102/311; H10K 2102/351

(57) ABSTRACT

Disclosed are a three-primary-light emitting stretchable mixed composition made of a polymer blend of a red/green/blue (RGB) light emitting polymer and a nonpolar elastomer, a stretchable light emitting mixed film prepared using the same and a stretchable polymer light emitting diode (PLED) device including the same. The stretchable light emitting mixed film according to the present disclosure can be composed of multidimensional nanodomains of a light emitting polymer interconnected within an elastomer to achieve efficient light emission under strain. The stretchable PLED device can exhibit a luminance of 1,000 cd/m² or more at a low turn-on voltage (<5 Vₒₙ) and can maintain stable light emitting performance up to a strain of 100% even after 1,000 repeated stretching cycles.

### CROSS-REFERENCE TO RELATED APPLICATION

This application claims priority to Korean Patent Application No. 10-2023-0125102, filed on Sep. 19, 2023 in the Korean Intellectual Property Office, the disclosure of which is incorporated herein by reference.

### BACKGROUND OF THE DISCLOSURE

### Field of the Disclosure

The present disclosure relates to a stretchable light emitting mixed composition, a stretchable light emitting mixed film prepared using the same and a stretchable polymer light emitting diode device comprising the same. More particularly, the present disclosure relates to a three-primary-color stretchable light emitting mixed film configured to realize excellent stretchability, elasticity and electrical performance using a light emitting polymer and an elastomer and a three-color PLED device including the same.

### Description of the Related Art

Stretchable displays, which exhibit stretchability, are receiving considerable attention as a form of next-generation display to expand applications for user interaction. Thereamong, a polymer light emitting diode (PLED) device led to the development of flexible displays. Recently, a stretchable PLED has been used as a core component of high-resolution stretchable displays due to its advantages such as high mechanical stretchability, color purity, color variability, resolution patterning, and power efficiency compared to previously reported stretchable light emitting devices such as light emitting capacitors and electrochemical light emitting devices.

To commercialize stretchable PLED, the development of stretchable light emitting films for producing stretchable displays is essential, and various types of films have been reported. The films can be broadly classified into two types. The first is an extrinsically elastic material, and the second is an intrinsically elastic material.

PLEDs with extrinsic stretchability are based on engineering structural deformations such as wrinkles/buckles, serpentine structures, and rigid islands. Although these approaches can be applied to commercial polymer light emitting materials, there are still challenges to be addressed regarding strain, device density, and light scattering for application to the deformation of human skin.

For intrinsically elastic PLEDs, significant advances in molecular design, molecular interaction control, and nano-confinement effects have been reported. For example, Kim's research group introduced an intrinsically elastic luminescent polymer film based on molecular interaction engineering using a plasticizer. They demonstrated that the inherent stretchability of an light emitting polymer (super yellow) can be improved by controlling the molecular bonding of a light emitting polymer using a surfactant as a plasticizer. This induced molecular sliding of entangled polymer chains, thus improving the intrinsic stretchability of high-brightness (>1,000 cd/m²) luminescent polymer films. However, stretchability luminescent films developed using a plasticizer are fundamentally ductile rather than elastic, so, if an elastic substrate is not provided, irreversible molecular slippage and fatigue failure can occur. Therefore, to develop an intrinsically elastic PLED, an elastic light emitting film that has high light emitting performance and is mechanically excellent under strain is required.

Polymer blends of luminescent polymers and elastomers have been proposed as a promising strategy to provide elasticity to luminescent polymer films. The nanoconfinement effect has been reported to transform a non-stretchable conjugated polymer into an intrinsically stretchable nanoconfined elastomer space because the increased chain dynamics of the nanoconfined conjugated polymer in an elastomer matrix can significantly reduce their Young's modulus. In this regard, Zhang's research group first applied the nanoconfinement effect to an intrinsically stretchable light emitting polymer film. Super yellow nanofibers nanoconfined in polyurethane (PU) showed higher stretchability (100% strain) and higher brightness (15,631 cd/m² at 0% strain on a rigid substrate) than previously reported intrinsically stretchable luminescent films.

To develop full-color displays, it is essential to fabricate three primary luminescent (red, green, and blue; RGB) films that are intrinsically stretchable. Although previous studies have reported the scalability of RGB emitting materials and their blends with elastomer matrices, research on stretchable RGB emitting films based on elastomer blends is still in its early stages. In addition, research to favor horizontal current in a substrate in terms of the improved morphology of a mixed film is ongoing to improve luminous efficiency compared to previously reported nanofiber-based mixed films. Therefore, intrinsically stretchable, high-brightness RGB emitting films that favor vertical current are still needed for full-color PLEDs with stretchability.

### RELATED ART DOCUMENT

### Non-Patent Document

J.-H. Kim, J.-W. Park, Intrinsically stretchable organic light emitting diodes. Sci. Adv. 7, eabd9715 (2021).

### SUMMARY OF THE DISCLOSURE

Therefore, the present disclosure has been made in view of the above problems, and it is an object of the present disclosure to provide an intrinsically elastic PLED and, for this purpose, to provide an elastic light emitting film that has high light emitting performance and is mechanically excellent under strain.

It is another object of the present disclosure to provide a stretchable three-basic-color (red, green, and blue; RGB)-light emitting film for application in full-color displays.

In accordance with an aspect of the present invention, the above and other objects can be accomplished by the provision of a stretchable light emitting mixed composition, including: a light emitting polymer including one of a red light emitting polymer, a green light emitting polymer and a blue light emitting polymer; an elastomer; and a solvent, wherein, in the stretchable light emitting mixed composition, the light emitting polymer is phase-separated from the elastomer into a plurality of nanodomains.

In an embodiment, the light emitting polymer may be phase-separated from the elastomer due to a difference between a surface energy of the light emitting polymer and a surface energy of the elastomer to form the plural nanodomains.

In an embodiment, a degree of phase separation may be adjusted depending upon a mixing ratio of the light emitting polymer to the elastomer.

In an embodiment, the light emitting polymer may be phase-separated into the plural nanodomains and the plural nanowebs depending upon a mixing ratio of the light emitting polymer to the elastomer, and the plural nanodomains and the plural nanowebs may be connected to each other.

In an embodiment, the red light emitting polymer and the elastomer may be mixed in a weight ratio of 9:1 to 1:9.

In an embodiment, the green light emitting polymer and the elastomer may be mixed in a weight ratio of 9:1 to 1:9.

In an embodiment, the blue light emitting polymer and the elastomer may be mixed in a weight ratio of 9:1 to 1:9.

In an embodiment, the light emitting polymer may be nonpolar.

In an embodiment, the elastomer may be nonpolar.

In an embodiment, the elastomer may be one selected from the group consisting of a Styrene-Ethylene-Butylene-Styrene (SEBS) block copolymer, a Styrene-Butadiene-Styrene (SBS) block copolymer, a Styrene-Isoprene-Styrene (SIS) block copolymer, a Styrene-Butadiene Rubber (SBR) block copolymer and a Styrene-Ethylene-Propylene-Styrene (SEPS) block copolymer.

In an embodiment, the light emitting polymer may have a conjugation structure.

In an embodiment, the red light emitting polymer may be a red-light emitting spiro-copolymer or a PPV-based copolymer.

In an embodiment, the green light emitting polymer may be a green-light emitting spiro-copolymer.

In an embodiment, the blue light emitting polymer may be poly(9,9-di-n-octylfluorenyl-2,7-diyl) (PFO) or a polyfluorene copolymer.

In accordance with another aspect of the present invention, there is provided a stretchable light emitting mixed film prepared using the stretchable light emitting mixed composition according to claim 1, wherein, in the stretchable light emitting mixed composition, the light emitting polymer is phase-separated from the elastomer into a plurality of nanodomains.

In an embodiment, when the stretchable light emitting mixed film is strained, a structure of the light emitting polymer may be preserved and the elastomer may be deformed.

In an embodiment, the stretchable light emitting mixed film may have a thickness of 50 nm to 130 nm.

In accordance with yet another aspect of the present invention, there is provided a stretchable polymer light emitting diode PLED device, including: a hole injection layer (HTL) formed on a lower electrode; an emitting layer (EML) formed on the hole injection layer and including the stretchable light emitting mixed film according to claim 12; an electron transport layer (ETL) formed on the light emitting layer; and an upper electrode formed on the electron transport layer.

In an embodiment, in the stretchable light emitting mixed film, the light emitting polymer may be phase-separated into the plural nanodomains and the plural nanowebs depending upon a mixing ratio of the light emitting polymer and the elastomer, and the plural nanodomains and the plural nanowebs may be connected to each other to enable isotropic transport of charges.

In an embodiment, the plural nanodomains and the plural nanowebs may be connected to each other so that charges recombine even when the stretchable polymer light emitting diode device is strained up to 100%.

### BRIEF DESCRIPTION OF THE DRAWINGS

The above and other objects, features and other advantages of the present disclosure will be more clearly understood from the following detailed description taken in conjunction with the accompanying drawings, in which:

FIGS. 1A to 1K schematically illustrate the improvement in stretchability and charge transport in an intrinsically stretchable mixed film made of an organic light emitting polymer forming a network structure of nanodomains and nanowebs;

FIGS. 2A to 2K show red and green light PLED;

FIGS. 3A to 3I show the stretchability and luminescence performance of a red, green and blue mixed film under various strain conditions; and

FIGS. 4A to 4H show the mechanical resistance and durability evaluation results of the red, green and blue mixed film.

### DETAILED DESCRIPTION OF THE DISCLOSURE

The present disclosure will now be described more fully with reference to the accompanying drawings and contents disclosed in the drawings. However, the present disclosure should not be construed as limited to the exemplary embodiments described herein.

The terms used in the present specification are used to explain a specific exemplary embodiment and not to limit the present inventive concept. Thus, the expression of singularity in the present specification includes the expression of plurality unless clearly specified otherwise in context.

It should not be understood that arbitrary aspects or designs disclosed in “embodiments”, “examples”, “aspects”, etc. used in the specification are more satisfactory or advantageous than other aspects or designs.

In addition, the expression “or” means “inclusive or” rather than “exclusive or”. That is, unless otherwise mentioned or clearly inferred from context, the expression “x uses a or b” means any one of natural inclusive permutations.

In addition, as used in the description of the disclosure and the appended claims, the singular forms “a”, “an” and “the” are intended to include the plural forms as well, unless context clearly indicates otherwise.

In addition, when an element such as a layer, a film, a region, and a constituent is referred to as being “on” another element, the element can be directly on another element or an intervening element can be present.

In this specification, a stretchable light emitting mixed composition or a stretchable light emitting mixed film includes a light emitting polymer and an elastomer, and a single light emitting composition includes a light emitting polymer.

In this specification, a nanodomain refers to a light emitting polymer that is phase-separated from an elastomer and aggregated into a spherical shape, and a nanoweb refers to a light emitting polymer that is phase-separated from an elastomer, has an expanded nanoscale semiconductor network structure and is aggregated in one dimension.

In this specification, strain includes stretching and bending, and a strain (%) refers to the ratio of a strained length to an initial state.

In this specification, a crack onset strain refers to a threshold value of a strain where a crack first occurs when a film or device is gradually deformed.

A light emitting mixed film with stretchability is a very important material for wearable displays. However, a color range was limited to yellow due to stretchable light emitting mixed films limited to the super yellow series. To develop a full-color display similar to skin color, three-primary-light emitting materials (red, green, and blue; RGB) with intrinsic stretchability are essential.

Accordingly, the present disclosure provides an intrinsically stretchable RGB light emitting film made of a mixture of an existing RGB light emitting polymer and an elastomer. For this purpose, a stretchable light emitting mixed composition is designed using low relative energy density and Flory-Huggins interaction parameter (x) value to ensure uniform mixing while suppressing serious phase separation.

A stretchable light emitting mixed film including a light emitting polymer and an elastomer mixture may have a crystal structure (crystallinity) similar to that of a single light emitting polymer film.

A stretchable light emitting mixed film can maintain its initial (before strain) crystallinity without mechanical damage up to 100% strain. That is, a stretchable light emitting mixed film may not be affected by strain in the crystal structure of a light emitting polymer. When a stretchable light emitting mixed film is deformed, the nanostructure of a light emitting polymer is preserved, and an elastomer may be mainly deformed. That is, the elastomer can mainly absorb the applied strain (external force) instead of the light emitting polymer. For this reason, even if the stretchable light emitting mixed film is deformed, these properties are maintained without affecting electroluminescence (EL), photoluminescence (PL), and luminance.

The stretchable light emitting mixed composition according to the present disclosure includes a light emitting polymer including one of a red light emitting polymer, a green light emitting polymer and a blue light emitting polymer; an elastomer; and a solvent. In the stretchable light emitting mixed composition, the light emitting polymer is phase-separated from the elastomer into a plurality of nanodomains. In polymer light emitting diode (PLED) devices, the stretchable light emitting mixed composition may be used as an emitting layer (EML).

According to an embodiment, the light emitting polymer may be phase-separated from the elastomer due to a difference between the surface energy of the light emitting polymer and the surface energy of the elastomer, thereby forming a plurality of nanodomains. Phase separation may occur at nano levels in the stretchable light emitting mixed composition. Such phase separation may result from a difference in surface energy between the light emitting polymer and the elastomer. The stretchable light emitting mixed composition exhibits uniform nano-phase separation, meaning that the light emitting polymer and the elastomer may be partially mixed.

According to an embodiment, the degree of phase separation may be adjusted depending upon a mixing ratio of the light emitting polymer and the elastomer. That is, the size of a dominant domain may vary depending on the mixing ratio.

As a difference in surface energy between the light emitting polymer and the elastomer is small, miscibility between the light emitting polymer and the elastomer increases, percolation becomes easier and the form of phase separation may be determined as nanodomains and nanowebs.

According to an embodiment, the light emitting polymer is phase-separated into a plurality of nanodomains and the plural nanowebs depending upon a mixing ratio of the light emitting polymer and the elastomer. Here, the plural nanodomains and the plural nanowebs may be connected to each other.

That is, nanodomains and nanowebs may be formed as the light emitting polymer and elastomer having similar surface energy are mixed. Here, when a mixing ratio of the light emitting polymer is small, several small nanodomains of the light emitting polymer may be formed in the elastomer, and phase separation may appear relatively clear. However, the size of light emitting polymer nanodomains may increase with increasing mixing ratio of the light emitting polymer.

The formed nanodomains and nanowebs are connected to each other, and one nanodomain and adjacent nanodomains can form a large network structure through the nanowebs. That is, the plural nanodomains may be connected to each other through the nanowebs. When such a phase separation network structure is used to implement a PLED device and transfer charges, it may serve as a transport path for charges, so charge mobility may be improved.

In a red, green, and blue stretchable light emitting mixed composition, nanodomain-based nanoweb phase separation may occur. Here, the nanodomain-based nanoweb phase separation refers to interconnected phase separation between nanodomains and nanowebs. The nanodomain and nanoweb phase separation favors current transport in both horizontal and vertical directions.

A difference in surface energy between the red light emitting polymer and the elastomer may be greater than a difference in surface energy between the green light emitting polymer and the elastomer and a difference in surface energy between the blue light emitting polymer and the elastomer. Phase separation may increase with increasing difference in surface energy between the light emitting polymer and the elastomer. However, the red light emitting polymer also has a surface energy similar to that of the elastomer, and a stretchable light emitting mixed film manufactured using the red light emitting polymer and the elastomer maintains its luminescent properties well when stretched, so that molecular-level nanowebs may be formed although not as well as green and blue light emitting polymers.

Hereinafter, the phase separation occurring in the stretchable light emitting mixed composition is described in detail. A stretchable light emitting mixed composition that emits three major RGB may have multidimensional nanodomains of a light emitting polymer in an elastomer. The spherical nanodomains of the light emitting polymer may be connected to each other in the form of one-dimensional (1D) nanowebs of a light emitting polymer, i.e., in the form of a molecular network. Accordingly, a device including the stretchable light emitting mixed composition as a light emitting layer may efficiently recombine electrons and holes injected from an electrode without mechanical damage up to 100% strain. Accordingly, the device may exhibit a strain-invariant high luminance of 1,000 cd/m² or more. Specifically, when deformed by 100% on a solid substrate, the red PLED device may exhibit a luminance of 1,731 cd/m², the green PLED device may exhibit a luminance of 1,807 cd/m² and the blue PLED device may exhibit a luminance of 2,167 cd/m². In addition, the intrinsically stretchable and mechanically durable RGB PLED device may maintain a luminance of 1,000 cd/m² or more at 100% strain for up to 1,000 repeated stretching cycles.

According to an embodiment, the red light emitting polymer and the elastomer may be mixed in a weight ratio of 9:1 to 1:9. Preferably, the red light emitting polymer and the elastomer may be mixed in a weight ratio of 5:5 to 2:8. More preferably, the red light emitting polymer and the elastomer may be mixed in a weight ratio of 3:7.

According to an embodiment, the green light emitting polymer and the elastomer may be mixed in a weight ratio of 9:1 to 1:9. Preferably, the green light emitting polymer and elastomer may be mixed in a weight ratio of 5:5 to 2:8. More preferably, the green light emitting polymer and elastomer may be mixed in a weight ratio of 2:8.

According to an embodiment, the blue light emitting polymer and the elastomer may be mixed in a weight ratio of 9:1 to 1:9. Preferably, the blue light emitting polymer and the elastomer may be mixed in a weight ratio of 5:5 to 3:7. More preferably, the blue light emitting polymer and the elastomer may be mixed in a weight ratio of 4:6.

In the stretchable light emitting mixed film, the red, green or blue light emitting polymer may form a uniform surface in the above ranges. The formation of a uniform surface means that the phase separation of the light emitting polymer and the elastomer occurs uniformly, which means that the stretchable light emitting mixed film is structurally stable.

When the elastomer is mixed below the range or the red, green or blue light emitting polymer is mixed above the range in the stretchable light emitting mixed composition, the Young's modulus of the stretchable light emitting mixed composition increases rapidly, so that a stretchable light emitting mixed film prepared using the stretchable light emitting mixed composition may become rigid and hard. Young's modulus tends to decrease as the mixing ratio of the elastomer increases. When the mixing ratio and Young's modulus of the elastomer greatly decrease and the mixing ratio of the elastomer exceeds the range, the Young's modulus is saturated, so that the Young's modulus reduction effect due to the elastomer may not increase even if the elastomer is mixed in a larger amount. When Young's modulus is less than 100 MPa, elasticity similar to that of human skin can be achieved, so the target value of Young's modulus may be set to less than 100 MPa.

In addition, when the elastomer is mixed below the range or the red, green or blue light emitting polymer is mixed above the range, the stretchable light emitting mixed film prepared using the stretchable light emitting mixed composition may exhibit poor stretchability due to rapidly reduced crack onset strain. When the elastomer is mixed below the mixing ratio, the crack initiation strain of the stretchable light emitting mixed film may greatly increase to 100% or more, and excellent stretchability may be exhibited.

On the other hand, when the elastomer is mixed above the range or the red, green or blue light emitting polymer is mixed below the range in the stretchable light emitting mixed composition, the luminance of a light emitting diode device including the stretchable light emitting mixed composition may be rapidly decreased. The mixing ratio of the red, green or blue light emitting polymer tends to be proportional to the luminance of a light emitting diode device, and the luminance of the red, green or blue light emitting polymer may be significantly decreased below the mixing ratio. However, when the elastomer is included within the mixing ratio, a similar luminance value may be maintained, compared to a light emitting diode device in which the red, green or blue light emitting polymer is only included. The movement of electrons may be facilitated by the percolation path caused by the nanowebs interconnected with the nanodomains of the light emitting polymer. That is, The nanoweb structure, which is one of the phase-separated forms of light emitting polymers, can penetrate and connect the elastomer matrix.

In addition, the elastomer may be an insulating material. The insulating properties of the elastomer may reduce the charge trap density of the light emitting polymer. The presence of the elastomer in a light emitting diode device containing the stretchable light emitting mixed composition dilutes the charge trap density and improves charge mobility, so the light emitting diode device may exhibit excellent luminance.

According to an embodiment, the light emitting polymer may be nonpolar. According to an embodiment, the elastomer may be nonpolar. If one of the elastomer and the light emitting polymer is polar and the other one thereof is nonpolar, the difference in surface energy becomes extreme and phase separation becomes severe, making it impossible to achieve a uniform distribution of the light emitting polymer within the elastomer matrix. In general, the surface energy level of a material increases with increasing polarity.

According to an embodiment, the elastomer may be one selected from the group consisting of a Styrene-Ethylene-Butylene-Styrene (SEBS) block copolymer, a Styrene-Butadiene-Styrene (SBS) block copolymer, a Styrene-Isoprene-Styrene (SIS) block copolymer, a Styrene-Butadiene Rubber (SBR) block copolymer and a Styrene-Ethylene-Propylene-Styrene (SEPS) block copolymer. Preferably, the elastomer may be SEBS.

The formula of SEBS as follows:

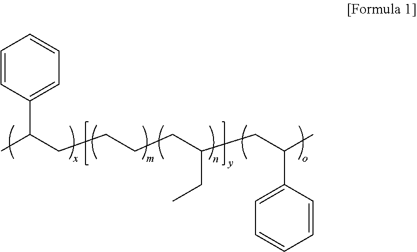

According to an embodiment, the light emitting polymer may have a conjugation structure. The conjugation structure improves electron mobility, so that conjugation polymers can exhibit electrical conductivity. In addition, the conjugation structure induces strong cohesion and intermolecular interactions, which can lead to the rigid properties of a light emitting polymer material.

According to an embodiment, the red light emitting polymer may be a red-light emitting spiro-copolymer or a PPV-based copolymer. Preferably, the red light emitting polymer may be a red-light emitting spiro-copolymer. More preferably, SPR-001 (hereinafter referred to as SP-red) may be used as the red light emitting polymer. SPR-001 has a weight average molecular weight of 180,000 g/mol.

According to an embodiment, the green light emitting polymer may be a green-light emitting spiro-copolymer. Preferably, SPG-01T (hereinafter referred to as SP-green) may be used as the green-light emitting spiro-copolymer.

SPG-01T has the following formula and a weight average molecular weight of 400,000 g/mol or more:

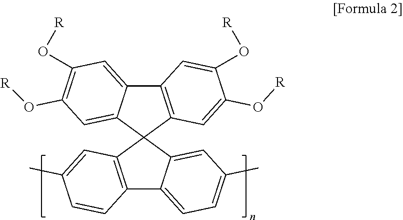

According to an embodiment, the blue light emitting polymer may be poly(9,9-di-n-octylfluorenyl-2,7-diyl) (PFO) or a polyfluorene copolymer. Preferably, the blue light emitting polymer may be PFO. PFO has the following formula and a weight average molecular weight of 20,000 g/mol or more:

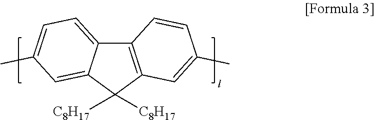

A solvent of the stretchable light emitting mixed composition may be one selected from the group consisting of toluene, chloroform, chlorobenzene and tetrahydrofuran (THF). Preferably, the solvent may be toluene.

The stretchable light emitting mixed film according to the present disclosure is fabricated using the stretchable light emitting mixed composition according to the present disclosure, and, in the stretchable light emitting mixed composition, the light emitting polymer is phase-separated from the elastomer into a plurality of nanodomains.

The light emitting performance of the stretchable light emitting mixed film may be maintained stably under strain because the light emitting polymer is phase-separated into nanodomains due to a difference in surface energy between the light emitting polymer and the elastomer. As the surface energy difference is small, miscibility between the light emitting polymer and the elastomer is high, and high miscibility enables phase separation in the form of a one-dimensional nanoweb. The light emitting polymer nanodomains and the nanowebs may be multidimensionally phase-separated in the form of a hybrid network. This network structure enables isotropic transport of charges in a light emitting diode containing a stretchable light emitting mixed film, and facilitates recombination of charges even if the stretchable light emitting mixed film is structurally strained. Accordingly, the dichroic ratio of the stretchable light emitting mixed film and the light emitting diode is maintained even when strained, so the light emitting performance of the light emitting diode may be maintained regardless of strain.

In addition, the hybrid network structure of the light emitting polymer within the elastomer may facilitate vertical and horizontal (parallel) transport of charges. Therefore, the stretchable light emitting mixed film and a light emitting diode including the same may maintain electrical properties without mechanical damage even under bi-axial strain.

According to an embodiment, the structure of the light emitting polymer may be preserved and the elastomer may be strained when straining the stretchable light emitting mixed film. That is, since the elastomer absorbs external force applied to the stretchable light emitting mixed film, the nano-phase separation structure of the light emitting polymer may maintain its shape. Accordingly, the stretchable light emitting mixed film may have excellent mechanical durability, and when the stretchable light emitting mixed film is used as a light emitting layer of a light emitting diode, high luminance may be accomplished even under strain. Therefore, such a stretchable light emitting mixed film may be effective in use as a stretchable display.

According to an embodiment, the thickness of the stretchable light emitting mixed film may be 50 nm to 130 nm. Preferably, the thickness of the stretchable light emitting mixed film may be 70 nm. When the thickness of the light emitting mixed film is less than 50 nm and greater than 130 nm, light dissipation may occur as a part where electrons and holes in the light emitting layer meet and emit light is excessively biased towards an upper or lower electrode.

The stretchable PLED device according to the present disclosure includes a hole injection layer (HTL) formed on a lower electrode, an emitting layer (EML) formed on the hole injection layer and including the stretchable light emitting mixed film according to the present disclosure, an electron transport layer (ETL) formed on the emitting layer (EML), and an upper electrode formed on the electron transport layer (ETL).

More particularly, the stretchable polymer light emitting diode device may have a laminated structure including a substrate, a lower electrode, a hole injection layer, a light emitting layer, an electron transport layer, and an upper electrode.

The substrate is a support for the stretchable polymer light emitting diode device and may include at least one of glass, stainless steel, plastic including polyethyleneterephthalate (PET), polyethylene naphathalate (PEN), polyethersulphone (PES) and polycarbonate (PC), quartz and metal. Preferably, the substrate is made of a transparent material. A light emitting diode measures the luminescence characteristics from the front or back side, and in the present disclosure, metal is used as an upper electrode. Accordingly, when an opaque substrate is used, difficulties may arise in determining the luminescence characteristics.

The lower electrode is formed on the substrate and may be an anode. The lower electrode injects holes into the hole injection layer. The lower electrode may be a transparent electrode. Here, the lower electrode may include at least one of metal oxides including indium tin oxide (ITO), indium zinc oxide (IZO), Al-doped zinc oxide (AZO), ZnO, SnO2 and In₂O₃, metal mash and graphene. Alternatively, the lower electrode may be a metal film layer. Here, the lower electrode may include at least one of Ag, Cu, Fe, Cr, W, Al, Mo, Zn, Ni, Pt, Pd, Co, In, Sn, V, Ru, Mg, Ta, Ir, Zr and alloys thereof.

The hole injection layer (HIL) is formed on the lower electrode and is a part where holes flow when current flows through the lower electrode and the light emitting diode device operates. The hole injection layer may include at least one of porphyrine, oligothiophene, arylamine-based organic materials, hexanitrile hexaazatriphenylene, quinacridone-based organic materials, perylene-based organic materials, PEDOT: PSS, anthraquinone and polyaniline and polythiophene-based conductive polymers.

The emitting layer (EML) is formed on the hole injection layer and is a part where light emission of the stretchable polymer light emitting diode device occurs. In the light emitting layer, holes and electrons respectively injected from the lower electrode and the upper electrode combine. Excitons generated at this time return to the ground state and emit light of a specific wavelength, causing light emission.

The electron transport layer (ETL) is formed on the light emitting layer and is a part that transports electrons from the light emitting diode device to the light emitting layer. The electron transport layer may include ZnO, Alq₃ and the like.

The upper electrode is formed on the electron transport layer, may be a cathode and serves to inject electrons. The upper electrode may be made of the same material as the lower electrode. The upper electrode may be a transparent electrode. Here, the upper electrode may include at least one of indium tin oxide (ITO), indium zinc oxide (IZO), Al-doped zinc oxide (AZO), ZnO, SnO₂, In₂O₃, metal mash and graphene. Alternatively, the upper electrode may include at least one of Al, Ag, Ca, Ca/Mg, Ca/Ag, Mg: Ag, Sm, Sm/Ag, Sm/Au, Yb/Au, Yb/Ag, Au and Al/SiO: Al.

According to an embodiment, depending upon a mixing ratio of the light emitting polymer and the elastomer in the stretchable light emitting mixed film, the light emitting polymer is phase-separated into a plurality of nanodomains and the plural nanowebs, and the plural nanodomains and nanowebs are mutually conttected to enable isotropic transport of charges.

According to an embodiment, since the plural nanodomains and nanowebs are mutually connected, charges may be recombined even when the stretchable polymer light emitting diode device is strained up to 100%.

The stretchable PLED device may exhibit high luminance exceeding 1,000 cd/m² up to 100% strain at a low turn-on voltages of less than 5 V. This luminance may be continued for 10,000 strain cycles. In addition, the stretchable PLED device may exhibit a luminance higher than 103 cd/m² when restored to its original state after 100% strain, and the turn-on voltage may be less than 5 V. A low turn-on voltage of less than 5V enables long-term electrical stability and savings in power consumption when used in wearable display applications such as electronic skin and medical fields.

When a nanofiber-based light emitting mixture composition is implemented into a PLED device, current flows smoothly only in the horizontal direction, but the stretchable PLED device according to the present disclosure facilitates the transport of charges in horizontal and vertical directions due to the light emitting layer of the interconnected network structure. Accordingly, the stretchable PLED device may maintain light emitting performance from a bending radius of 5 mm to a bending angle of 100°. In addition, the stretchable PLED device may exhibit a luminance of more than 1,000 cd/m² when bi-axially stretched up to 30%.

Hereinafter, embodiments of the present disclosure will be described in detail with reference to the attached drawings. These embodiments are for illustrating the present disclosure in more detail, and the scope of the present disclosure is not limited by these examples.

### [Examples 1-1 to 1-6] Red Mixed Film

A red-light emitting spiro-copolymer (SPR-001, purchased from Sigma-Aldrich, product No. 900444, average molecular weight: 180,000) as a light emitting polymer and an elastomer as SEBS were added to toluene and mixed in a weight ratio shown in Table 1 below to prepare a stretchable red light emitting polymer solution. The stretchable red light emitting polymer solution was stirred at 80° C. for 2 hours. Here, the solution was prepared at a concentration of 1% by weight. The red light emitting polymer solution was spin-coated on a TFB film at 1,000 rpm over 60 seconds and annealed in a 130° C. vacuum oven for 30 minutes.

### [Comparative Example 1] Red Single Film

A red single film was fabricated in the same manner as in Example 1-1 except for the mixing of SEBS.

### [Examples 2-1 to 2-6] Green Mixed Film

A green single film was fabricated in the same manner as in Example 1-1 except that a green-light emitting spiro-copolymer (SPG-01T, purchased from Sigma-Aldrich, product No. 900441) instead of a red-light emitting spiro-copolymer was used as a light emitting polymer. The green-light emitting spiro-copolymer and SEBS were mixed in a weight ratio shown in Table 1 below.

### [Comparative Example 2] Green Single Film

A red single film was fabricated in the same manner as in Example 2-1 except for the mixing of SEBS.

### [Examples 3-1 to 3-6] Blue Mixed Film

A blue single film was fabricated in the same manner as in Example 1-1 except that poly(9,9-di-n-octylfluorenyl-2,7-diyl) (PFO, purchased from Sigma-Aldrich, product No. 571652, Blue) instead of a red-light emitting spiro-copolymer was used as a light emitting polymer. PFO and SEBS were mixed in a weight ratio shown in Table 1 below.

### [Comparative Example 3] Blue Single Film

A blue single film was fabricated in the same manner as in Example 3-1 except for the mixing of SEBS.

TABLE 1

| | Weight ratio of light emitting polymer:SEBS | | | | | | |
|---|---|---|---|---|---|---|---|
| | | | | | Red/green 3:7 | Red/green 2:8 | |
| Film | 10:0 | 9:1 | 7:3 | 5:5 | blue 4:6 | blue 3:7 | 1:9 |
| Red | Comparative | Example 1-1 | Example 1-2 | Example 1-3 | Example 1-4 | Example 1-5 | Example 1-6 |
| | Example 1 | | | | | | |
| Green | Comparative | Example 2-1 | Example 2-2 | Example 2-3 | Example 2-4 | Example 2-5 | Example 2-6 |
| | Example 2 | | | | | | |
| Blue | Comparative | Example 3-1 | Example 3-2 | Example 3-3 | Example 3-4 | Example 3-5 | Example 3-6 |
| | Example 3 | | | | | | |

### [Examples 4-1 to 4-6] Red PLED Device

The patterned ITO substrate was sequentially washed with DI water, acetone and isopropyl alcohol for 15 minutes using an ultrasonic device (DH.WUC.A03H, DAIHAN-scientific). Next, to increase hydrophilicity, the substrate was treated with ultraviolet-ozone (UVC-150, Omniscience) for 15 minutes to form an anode.

PEDOT: PSS dispersed in DI water was spin-coated on the ITO substrate at 3,000 rpm for 30 seconds and annealed in a 150° C. vacuum oven for 15 minutes to form a hole injection layer (HIL). Next, TFB precursor was dissolved in p-xylene to prepare a 1 wt % TFB solution for a hole injection layer (HTL). Next, 1 wt % TFB solution was stirred at 80° C. for 1 hour. The stirred solution was spin-coated on the PEODT: PSS film at 3,000 rpm for 30 seconds and annealed in a 180° C. vacuum oven for 30 minutes to form a hole transport layer (HTL).

The film fabricated in each of Examples 1-1 to 1-6 was transferred from the OTS-treated silicon wafer to the ITO substrate to form a stretchable emitting layer (EML).

ZnO was spin-coated at 2,000 rpm for 60 seconds, and then annealed in a 60° C. vacuum oven for 10 minutes to form an electron transport layer (ETL). The entire process was performed under a vacuum or inert condition.

Finally, a 130 nm aluminum electrode was deposited using a thermal evaporator to form a cathode.

### [Examples 5-1 to 5-6] Fabrication of Green PLED Device on ITO Substrate

A green PLED device was fabricated in the same manner as in Example 4-1 except that the film of each of Examples 2-1 to 2-6 was used to form a stretchable emitting layer (EML).

### [Examples 6-1 to 6-6] Fabrication of Blue PLED Device on ITO Substrate

A blue PLED device was fabricated in the same manner as in Example 4-1 except that the film of each of Examples 3-1 to 3-6 was used to form a stretchable emitting layer (EML).

As a result, Examples 4-1 to 6-6 were fabricated as shown in Table 2 below.

TABLE 2

| | Light emitting polymer:SEBS | | | | | | |
|---|---|---|---|---|---|---|---|
| PLED | | | | | Red/green 3:7 | Red/green 2:8 | |
| device | 10:0 | 9:1 | 7:3 | 5:5 | blue 4:6 | blue 3:7 | 1:9 |
| Red | Comparative | Example 4-1 | Example 4-2 | Example 4-3 | Example 4-4 | Example 4-5 | Example 4-6 |
| | Example 4 | | | | | | |
| Green | Comparative | Example 5-1 | Example 5-2 | Example 5-3 | Example 5-4 | Example 5-5 | Example 5-6 |
| | Example 5 | | | | | | |
| Blue | Comparative | Example 6-1 | Example 6-2 | Example 6-3 | Example 6-4 | Example 6-5 | Example 6-6 |
| | Example 6 | | | | | | |

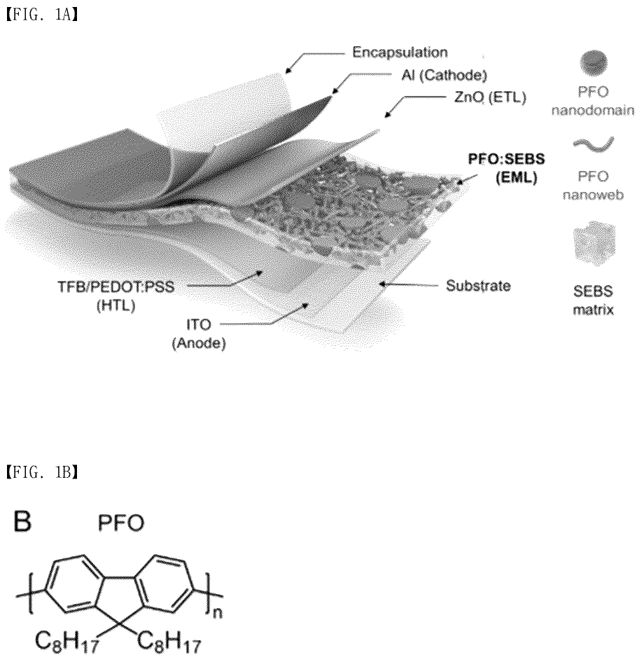

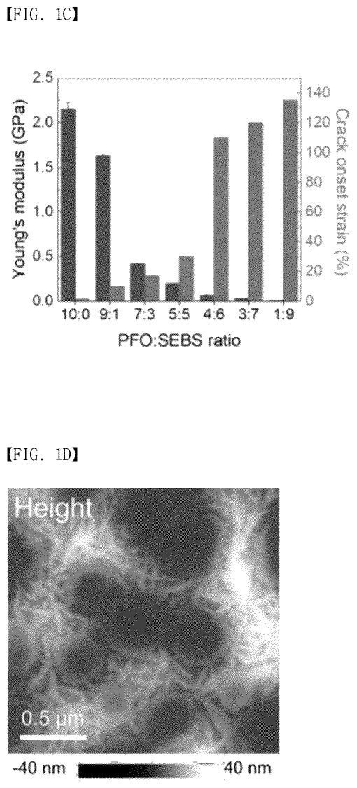

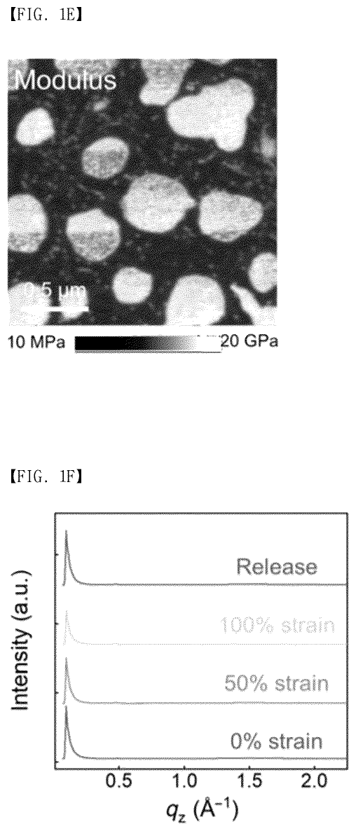

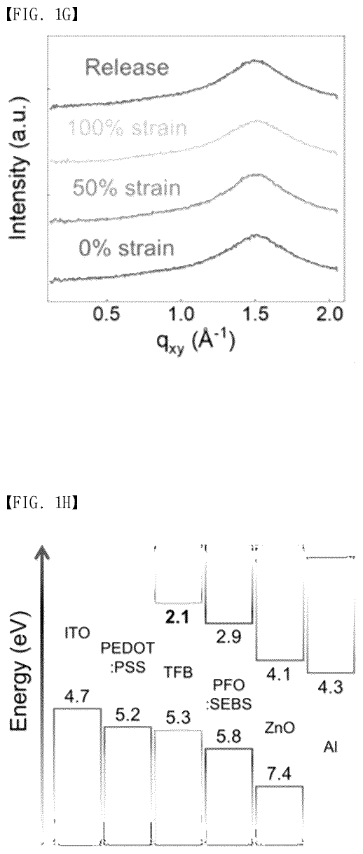

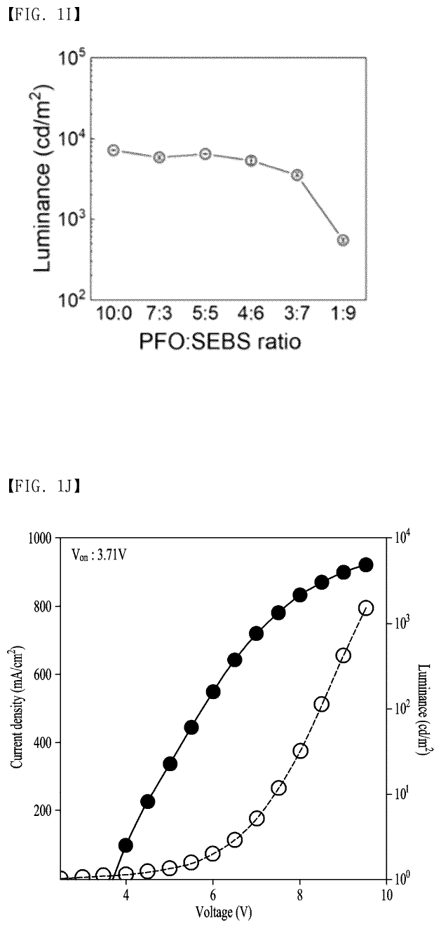

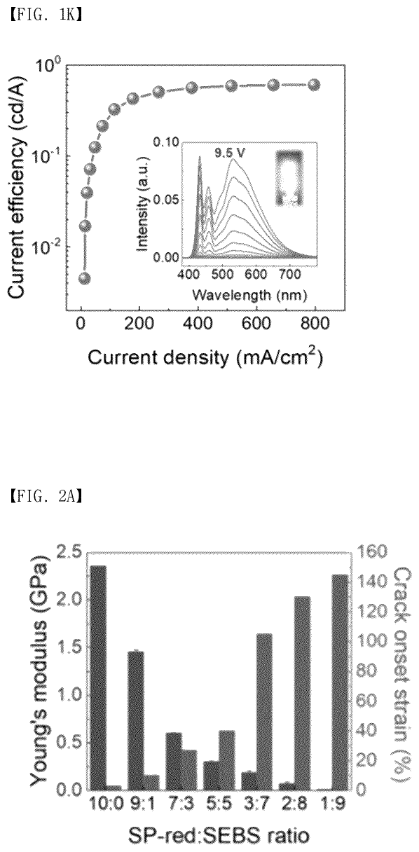

FIG. 1A is a schematic diagram illustrating the structure of the blue PLED device. poly(9,9-di-n-octylfluorenyl-2,7-diyl) (PFO) as a blue light emitting polymer was mixed with a styrene-ethylene-butylene-styrene (SEBS) elastomer to prepare a light emitting film, and the chemical structure of PFO is shown in FIG. 1B. Here, a mixing ratio of PFO:SEBS was optimized depending upon the changed crack onset strain of the film and the Young's modulus thereof.

### [Examples 7-1 to 7-6] Transfer of Stretched Red Mixed Film on PLED Device

An OTS SAM-treated silicon wafer was prepared to easily separate a film. First, an OTS solution was prepared by dissolving it in anhydrous chloroform (5 mg/ml). This solution was spin-coated at 2,000 rpm for 60 seconds on a silicon wafer treated with O₂ plasma for 60 seconds in PE mode. The spin-coated silicon wafer was annealed in ammonium hydroxide vapor (25° C.) for 4 hours. The EML solution (red light emitting polymer solution) of each of Examples 1-1 to 1-6 was spin-coated on OTS silicon wafer at 1,000 rpm for 60 seconds and annealed in a 130° C. vacuum oven for 30 minutes. Once the film was fully prepared, it was transferred to PDMS using a fast separation process. PDMS was mixed with a cross-linker in a weight ratio of 10:1 and cured at 60° C. overnight. The film transferred to PDMS was stretched under various strain conditions such as 0, 25, 50, 75, and 100%, and then transferred back to the PLED device as in Examples 2-1 to 2-6 to produce a PLED device including the stretched red mixed film.

### [Examples 8-1 to 8-6] Transfer of Stretched Green Mixed Film to PLED Device

PLED devices were produced in the same manner as in Examples 7-1 to 7-6 except that the EML solution (green light emitting polymer solution) of Examples 2-1 to 2-6 was used instead of the EML solution (red light emitting polymer solution) of Examples 1-1 to 1-6.

### [Examples 9-1 to 9-6] Transfer of Stretched Green Mixed Film on PLED Device

PLED devices were produced in the same manner as in Examples 6-1 to 6-6 except that the EML solution (blue light emitting polymer solution) of Examples 3-1 to 3-6 was used instead of the EML solution (red light emitting polymer solution) of Examples 1-1 to 1-6.

### [Experimental Example 1] Evaluation of Mechanical Properties Dependent Upon Mixing Ratio of Elastomer to Light Emitting Polymer-Blue

FIG. 1C illustrates Young's moduli and crack onset strains (COS) dependent upon the PFO:SEBS mixing ratios of the films of Comparative Example 3 and Examples 3-1 to 3-6. As the ratio of the SEBS elastomer increases, the Young's modulus of the mixed film was greatly decreased as follows: 1.63 GPa in a PFO:SEBS mixing ratio of 9:1 and 415 MPa in a PFO:SEBS mixing ratio of 7:3. In addition, the Young's modulus of the film was saturated to 9 MPa in a PFO:SEBS mixing ratio of 1:9.

In addition, referring to FIG. 1C, the crack onset strain of the light emitting mixed film was about 10% in a PFO:SEBS mixing ratio of 9:1, and greatly increased to 100% or more in a PFO:SEBS of mixing ratio 4:6.

### [Experimental Example 2] Phase Analysis-Blue

Atomic force microscopy (AFM) was performed using the peak force quantitative nanomechanical mapping (QNM) method to investigate the nanoscale morphology of the controlled blend films.

FIGS. 1D and 1E respectively show the height and modulus images of Example 3-4. The PFO:SEBS mixed film exhibited multidimensional hybrid phase separation based on spherical and rod-shaped PFO nanodomains interconnected like a nanoweb structure corresponding to the modulus (˜4 GPa) of a single PFO film.

Table 3 shows the surface energy and contact angle (CA) for each of DI water and diiodomethane of Comparative Examples 1 to 3 and Examples 1-4, 2-5 and 2-4. The phase separation of the mixed polymer results from the surface energy difference between PFO (36.3 mJ/m²) and SEBS (33.6 mJ/m²), which can be converted to the interaction parameter (χ) (χ_{PFO:SEBS} 0.05K).

TABLE 3
Surface energy (γ) and interaction parameter (χ) of light emitting film

| | | Contact Angle (°) | | Surface Energy (mJ/m²) | | | Interaction |
|---|---|---|---|---|---|---|---|
| | | DI-water | Diiodomethane | [symbol] | [symbol] | [symbol] | parameter ( [symbol] ) |
| Neat | PFO | 103.2 | 46.4 | 36.3 | 36.3 | 0.82 × 10 [symbol] | [symbol] |
| | SP-red | 91.6 | 34.8 | 41.8 | 41.4 | 0.45 | — |
| | SP-green | 96.7 | 41.7 | 38.7 | 38.3 | 0.40 | — |
| | PFO:SEBS | 95.6 | 50.2 | 34.1 | 33.4 | 0.77 | 0.05K |
| Blend | SP-green:SEBS | 103.5 | 49.9 | 34.3 | 34.3 | 0.59 × 10 [symbol] | 0.17K |
| | SP-red:SEBS | 103.1 | 48.9 | 34.9 | 34.8 | 0.39 × 10 [symbol] | 0.45K |

[symbol]

indicates data missing or illegible when filed

Solubility parameters for calculating relative energy density (RED) are shown in Table 4 below. The relative energy density (RED) of PFO and SEBS mixed system is 0.85 which is less than 1, suggesting that the materials are miscible with each other.

TABLE 4
Solubility parameters for calculating relative energy density (RED)

| | | | | | sphere |
|---|---|---|---|---|---|
| Material | δ_{D} | δ [symbol] | δ [symbol] | δ [symbol] | radius (R [symbol] ) |
| PFO | 18.55 | 2.8 | 4.51 | 19.81 | 4.1 |
| SEBS | 16.388 | 0.198 | 0 | 16.39 | 8 |

δ [symbol] dispersive solubility parameter
δ [symbol] polar solubility parameter
δ [symbol] hydrogen [symbol] parameter
δ [symbol] Hansen solubility parameter [symbol]
indicates data missing or illegible when filed

The mixed films were produced to the same thickness and at the same concentration to better observe morphological changes, and AFM height and AFM phase images were analyzed. The mixed films with various mixing ratios (PFO:SEBS, 1:9˜9:1) showed uniform nano-phase separation, indicating that PFO and SEBS could be partially mixed. When PFO and SEBS are mixed, PFO nanodomain and nanoweb structures are formed and interconnected, facilitating vertical and horizontal charge carrier transport without mechanical damage. AFM surface morphology analysis confirmed that a uniform surface was formed from the time PFO was mixed in a ratio of 40% by weight in the mixed films.

### [Experimental Example 3] Crystallinity Analysis—Blue

To better understand the nanostructures of PFO and SEBS mixed films, the crystallinity of the mixed films was investigated using grazing-incidence wide-angle X-ray scattering (GIWAX). GIWAXS of the polymer film on the silicon wafer was measured in Xeuss 2.0 (Xenocs Inc) with an X-ray wavelength of 1.54 Å, a distance of 15 cm from a sample to a detector, and an angle of incidence of 0.2°. Examples were kept under vacuum to minimize air scattering. Diffraction images were recorded by a Pilatus 1M detector (Dectris Inc.) and processed using the Nika software package with WAXSTools wavemetrics Igor.

FIGS. 1F and 1G show crystallinity and 1D diffraction intensity curve in two directions, out-of-plane and in-plane, which are extracted from GIWAX analysis data of the mixed film of Example 3-4 under various strain conditions. From this, it can be confirmed that the mixed film shows crystallinity similar to that of the single PFO film, and that the phase-separated PFO of the mixed film has a typical crystal structure similar to that of the single PFO film. In addition, the mixed film maintained its initial crystallinity without mechanical damage up to 100% strain, proving that the PFO crystal structure of the mixed film is not affected by strain.

### [Experimental Example 4] Dichroic Ratio Analysis-Blue

Example 3-4 was analyzed by polarized UV-vis spectroscopy under various strain conditions, and the dichroic ratio was determined by Iₚₐᵣₐₗₗₑₗ/I_{perpendicular}. The dichroic ratio of the mixed film maintained the initial value (1.02) up to 100% strain, which suggests that the nanostructure of PFO is preserved and SEBS is mainly elongated when strained. The dichroic ratio, as a ratio of the polarized UV-vis absorption peak ratio between perpendicular light (∥) and parallel light (=), which indicates the molecular alignment of the conjugation polymer, was maintained constant. This is consistent with the result that the mixed film maintained its initial crystallinity without mechanical damage up to 100% strain.

### [Experimental Example 5] Electroluminescence (EL) Evaluation—Blue

Based on the morphology and crystallinity analysis results, a PLED device was manufactured with PFO:SEBS mixed film, and electroluminescence (EL) performance was evaluated. The electroluminescence (EL) characteristics of PLED were measured using a source-meter unit (K-2400, Keithley)

The PLED device structure and its interface energy band alignment were designed to achieve high luminance. FIG. 1H illustrates the energy band diagrams of all components of Example 6-4. The components are as follows: ITO (anode), PEDOT: PSS (HIL), TFB (HTL), PFO:SEBS (EML), ZnO (ETL) and Al (cathode). FIG. 1I illustrates changes in luminance dependent upon the PFO:SEBS mixing ratio in the PLED devices according to Comparative Example 6 and Examples 6-1 to 6-6. It can be seen that the electroluminescence (EL) performance is almost maintained up to 60% of the SEBS weight.

### [Experimental Example 6] Current Density-Voltage-Luminance (J-V-L) Evaluation—Blue

The current density-voltage-luminance (J-V-L) characteristics of PLED were measured using a J-V-L measurement system (M6100, McScience) connected to a spectroradiometer (CS-2000, Konica Minolta).

FIG. 1J illustrates the current density, voltage and luminance of Example 6-4. The light emitting films with various mixing ratios (PFO:SEBS) showed maximum luminance values of 7,081 cd/m² (mixing ratio: 10:0), 6,149 cd/m² (mixing ratio: 7:3), 6,471 cd/m² (mixing ratio: 5:5), 5,823 cd/m² (mixing ratio: 4:6), 3,777 cd/m² (mixing ratio: 3:7) and 573cd/m² (mixing ratio: 1:9). PLED using PFO:SEBS (mixing ratio: 4:6) light emitting mixed film maintained a luminance value of about 82%, compared to the case where a single PFO film was used, even though the light emitting mixed film consisted of 60% by weight of insulating SEBS. This result may be due to the percolation pathway of nanowebs interconnected with the PFO domains. That is, since the insulating elastomer can reduce the charge trap density of the conjugation polymer, the charge trap density may be diluted in light emitting mixed films.

To demonstrate this mechanism, a single film and a light emitting mixed film were applied to time-resolved photoluminescence, electron-only devices (EOD) and hole-only devices (HOD) and evaluation was performed.

### [Experimental Example 7] Photoluminescence (PL) Analysis-Blue

The photoluminescence (PL) spectrum of the stretchable emitting layer (EML) was obtained using a 365 nm UV lamp (VL-6.LC, Vilber Lourmat).

The EOD device was fabricated in a structure of ITO (glass)/light emitting polymer: SEBS/ZnO/Al, and the HOD device was fabricated in a structure of ITO (glass)/PEDOT: PSS/TFB/light emitting polymer: SEBS/PEDOT: PSS/Ag. The components of the EOD and HOD devices were spin-coated and annealed under the optimized conditions mentioned above. In addition, to obtain a uniform film, 0.25 wt % Triton-X was added to PEDOT: PSS as an electron-blocking layer on the HOD. Compared to the Al electrode, the Ag electrode on HOD was deposited up to 70 nm at a deposition rate of 2.0 Å/s.

The time-resolved photoluminescence (TRPL) spectra of Comparative Example 3 (neat PFO) and Example 3-4 (PFO:SEBS mixed light emitting layer) were analyzed, and photon currents were obtained by time flow using a blue luminescent film on a quartz substrate. Comparative Example 3 and Example 3-4 were excited using a 365 nm wavelength pulsed laser. The average photoluminescence (PL) lifetime of the single PFO and PFO:SEBS light emitting mixed films decreased slightly from 0.33 ns to 0.30 ns. This result means that no additional traps were formed after mixing with the SEBS elastomer.

The charge carrier transport characteristics of the hole-only devices (HOD) and the electron-only devices (EOD) were evaluated, and each current density-voltage curve was measured using HOD and EOD devices to which the films of Comparative Example 3 and Example 3-4 were applied, respectively. In EOD, the electron current density slightly increased from 140 mA/cm² (single PFO film) to 407 mA/cm² (PFO:SEBS mixed film). In HOD, the hole current density increased from 130 mA/cm² (single PFO film) to 425 mA/cm² (PFO:SEBS mixed film).

FIG. 1K illustrates the current efficiency and current density of PLED using the PFO:SEBS (mixing ratio: 4:6) light emitting film according to Example 3-4. The drawing inserted in the graph shows the electroluminescence (EL) spectrum below 9.5V and the light emitted by the PLED device. Referring to FIG. 1K, the diluted charge trap resulted in a stable current efficiency of 0.6 cd/A at 800 mA/cm². Referring to the inserted drawing of FIG. 1K, the emission wavelength of the light emitting mixed film showed some dependence on the operating voltage.

Hereinafter, to generalize the characteristics evaluation results of the blue light emitting polymer by applying them to other primary color light emitting polymers, two spiro-copolymers emitting red (spiro-red, SP-red) and green (spiro-green, SP-green) light were applied to the mixing system using the SEBS elastomer.

### [Experimental Example 8] Evaluation of Mechanical Properties-Red, Green

The mixing ratios of the red and green light emitting polymers and the SEBS mixed film were controlled by setting Young's modulus to a lower value than human skin and setting stretchability under 100% strain, as in the PFO:SEBS mixed system.

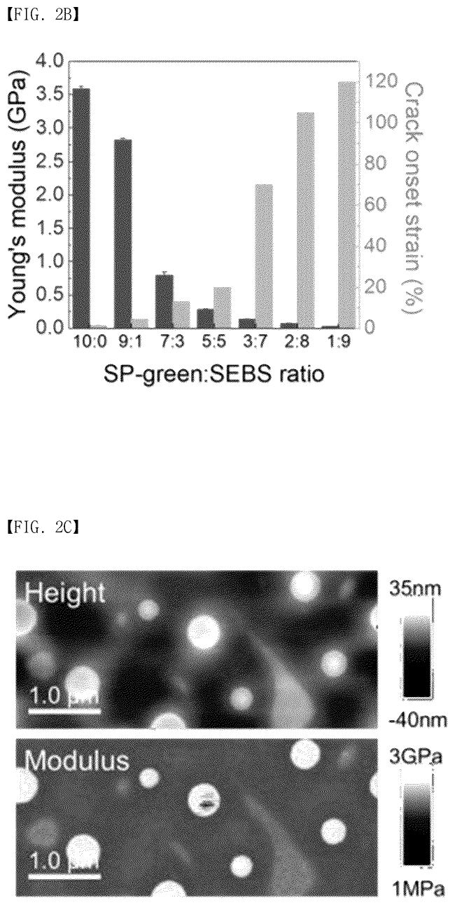

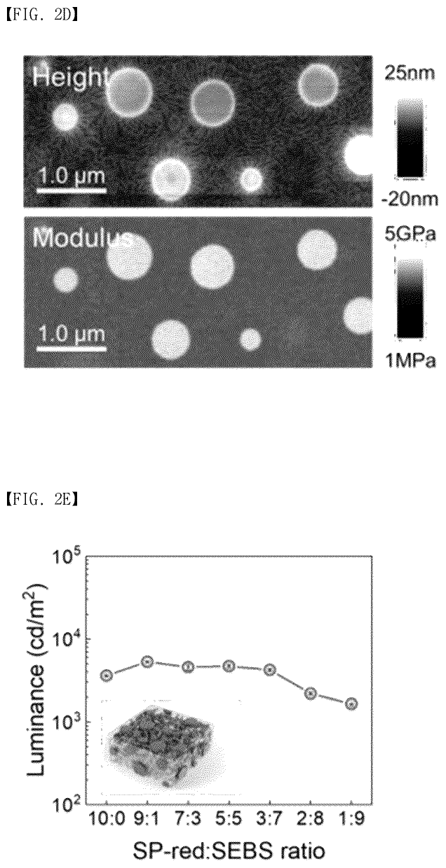

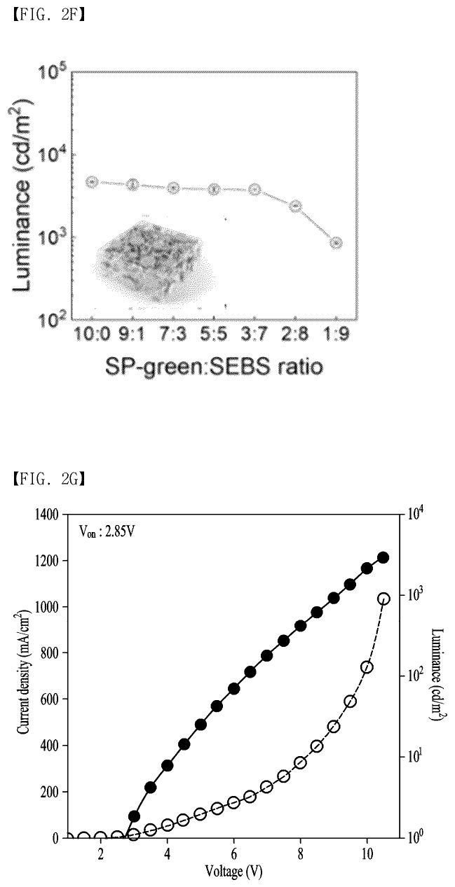

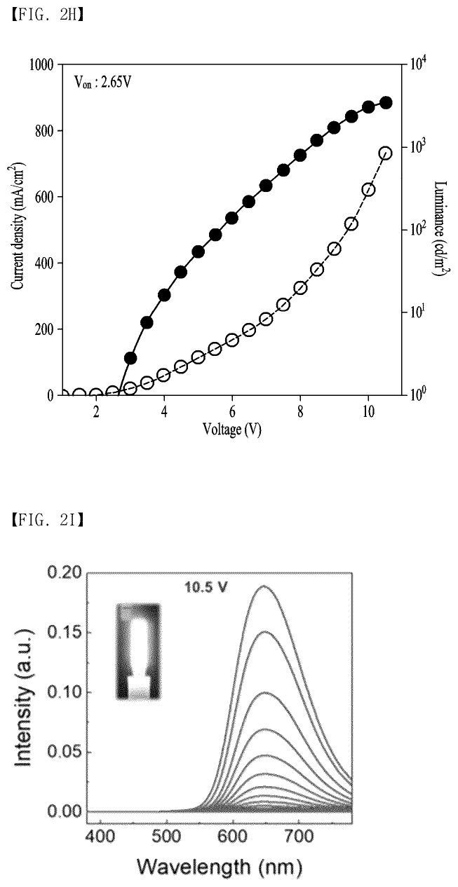

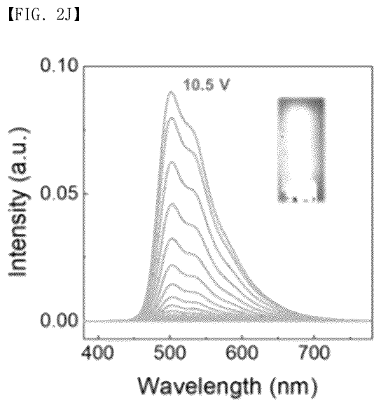

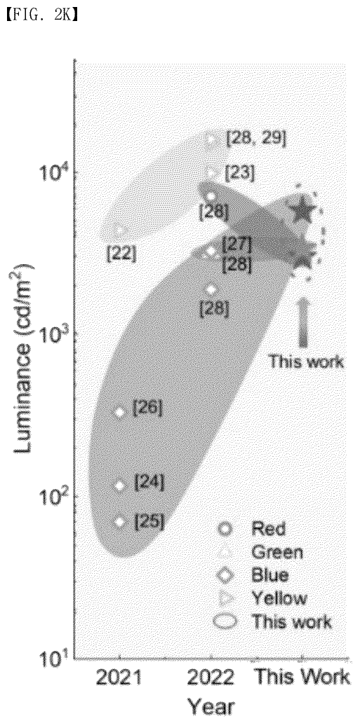

FIG. 2A illustrates the Young's modulus and COS of the SP-red of Comparative Example 1 and Examples 1-1 to 1-6. FIG. 2B illustrates the Young's moduli and COS graphs of SP-red and SP-green of Comparative Example 2 and Examples 2-1 to 2-6. The mixed films with mixing ratios of 3:7 (SP-red: SEBS) and 2:8 (SP-green: SEBS) satisfied stretchability (100% or more) and Young's modulus requirements (102 MPa or less which is an average elastic modulus range of human skin) for red and green emission, respectively.

### [Experimental Example 9] Film Formation Kinetics Analysis-Red, Green, Blue

The shear stress and shear viscosity (n) of the trichromatic solution as a function of shear rate were measured for film formation kinetics. The viscosity values of the RGB mixed solutions were similar (green: 1.80 cP, blue: 1.12 cP and red: 0.64 cP at a shear rate of 16/s, similar to the spin coating speed), which affects the phase separation of the mixed film. QNM analysis provided the Young's modulus and material identification of each component within the separated phase.

FIGS. 2C and 2D illustrate images of the AFM height (top) and DMT coefficient (bottom) of Example 1-4 and Example 2-5, respectively. The SP-green: SEBS mixed film showed nanoweb phase separation based on nanodomains similar to the PFO:SEBS mixed film, while the SP-red: SEBS mixed film showed only nanodomain-based phase separation. The phase separation of the light emitting mixed film is mainly caused by a difference in surface energy between a light emitting polymer and SEBS. The single SP-green film showed a similar surface energy (38.6 mJ/m²) to PFO and SEBS, but the single SP-red film showed a higher surface energy (41.8 mJ/m²) than the other films. Using this surface energy, the χ values of the green and red mixed films were determined to be χSP-green: SEBS 0.17K and χSP-red: SEBS 0.45K, respectively (Table 3). The high χSP-red: SEBS value of the red mixed film resulted in relatively more phase separation, which may be the cause of nanodomain-based phase separation that is the only phase separation in the red mixed film.

To analyze phase separation in detail, the nanoscale forms of the red and green light emitting films with different mixing ratios (SP-red: SEBS and SP-greed: SEBS; 9:1 to 1:9) were further analyzed using AFM. The red and green light emitting films showed phase separation similar to the blue light emitting film as the SEBS content increased.

### [Experimental Example 10] Crystallinity Analysis-Red, Green

GIWAX analysis was performed to analyze the crystallinity of the green and red mixed films. The GIWAX spectrum supports that all mixed films maintain their initial crystallinity up to 100% strain, indicating that the SEBS elastomer matrix primarily absorbs the applied strain instead of a light emitting polymer domain.

### [Experimental Example 11] Current Density-Voltage-Luminance (J-V-L) Evaluation-Red, Green

FIGS. 2E and 2F illustrate that the luminance of the red and green PLED devices using Comparative Example 1, Examples 1-1 to 1-6, Comparative Example 2 and Examples 2-1 to 2-6 changes depending upon a mixing ratio.

Major EL characteristics such as luminance, current density and current efficiency were evaluated on an indium tin oxide (ITO)-glass rigid substrate. The PLED devices with SP-red: SEBS mixed film ratios of 0 to 90% by weight of SEBS showed maximum luminance values of 3,698 cd/m² (mixing ratio: 10:0), 5,135 cd/m² (mixing ratio: 9:1), 4,907 cd/m² (mixing ratio: 7:3), 4,460 cd/m² (mixing ratio: 5:5), 4,061 cd/m² (mixing ratio: 3:7), 2,280 cd/m² (mixing ratio: 2:8) and 1,639 cd/m² (mixing ratio: 1:9). For the same change in SEBS content of the SP-green mixed film, the PLED devices shows maximum luminance values of 4,746 cd/m² (mixing ratio: 10:0), 4,003 cd/m² (mixing ratio: 9:1), 4,060 cd/m² (mixing ratio: 7:3), 4,030 cd/m² (mixing ratio: 5:5), 3,756 cd/m² (mixing ratio: 3:7), 2,418 cd/m² (mixing ratio: 2:8) and 886 cd/m² (mixing ratio: 1:9).

Regarding the performance of the red and the green PLED devices, the performance of the red PLED device in which SEBS was up to 70% by weight and the performance of the green PLED device in which SEBS was up to 80% by weight were almost the same as that of the single light emitting polymer film without SEBS. Finally, the optimal mixing ratios of SP-red and SP-green mixed films were analyzed to be 3:7 (SP-red: SEBS) and 2:8 (SP-green: SEBS), respectively, based on high performance and sufficient stretchability.

The J-V-L curves of the optimized red-emitting PLED device (Example 4-4) and green-emitting PLED device (Example 5-5) are shown in FIGS. 2G and 2H, respectively. FIGS. 2G and 2H illustrate the current density and luminance versus voltage of each of PLEDs using 30% SP-red and 20% SP-green mixed films. Both the devices showed a typical PLED J-V-L curve with low turn-on voltage (2.85 Von for red and 2.65Von for green at 1cd/m² luminance). These results imply that red and green PLEDs have appropriate band alignment for efficient radiative recombination of electrons and holes injected from a cathode and an anode.

### [Experimental Example 12] Photoluminescence (PL) Analysis-Red, Green

To compare average lifespans, the time-resolved photoluminescence (TRPL) spectra of the single light emitting layers (Comparative Examples 1 and 2) and the mixed light emitting layer (Examples 1-4 and 2-5) were analyzed. The photoluminescence (PL) spectrum of the stretchable emitting layer (EML) was acquired from a 365 nm UV lamp (VL-6.LC, Vilber Lourmat), and the photon current was obtained by time flow using red and green light emitting films on a quartz substrate. Examples were excited using 470 nm and 405 nm wavelength pulsed lasers, respectively. As a result, the photoluminescence (PL) lifespans of SP-red: SEBS and SP-green: SEBS mixed films were slightly decreased.

To evaluate charge carrier transport characteristics, Current density-voltage curves were measured in the hole-only devices (HOD) and the electron-only devices (EOD). the electron current density of the red and green mixed films increased from 55 mA/cm² (SP-red single) to 210 mA/cm² (SP-red: SEBS 3:7 mixed) and from 151 mA/cm² (SP-green single) to 2, 180 mA/cm² (SP-green: SEBS 2:8 mixed). The hole current density of the red and green mixed films in the HOD devices increased from 29 mA/cm² (SP-red single) and 6 mA/cm² (SP-green single) to 38 mA/cm² (SP-red: SEBS 3:7 mixed) and 17 mA/cm² (SP-green: SEBS mixed). That is, due to charge trap dilution, in the case of the mixed light emitting polymer film mixed with the SEBS elastomer, the charge density and charge carrier transport of the electron and hole carrier were improved compared to the single light emitting polymer film. However, as the SEBS content increased up to 90% by weight, the overall luminance values of all the mixed films decreased. This result means that the absolute content of the light emitting polymer in the mixed film predominantly affects the light emitting performance.

The electroluminescence (EL) spectra of the red and green PLED devices are shown with the application of operating voltage in FIGS. 21 and 2J. FIGS. 21 and 2J illustrate the EL spectra of the PLED devices of Examples 4-4 and 5-5 and show the same peak position during the applied voltage sweep. The peak positions of EL were 645 nm and 504 nm with no peak shift. To compare the basic color luminance values of the mixed films in an initial (pristine) state, the previously reported stretchable RGB color luminance values were analyzed and shown in FIG. 2K. FIG. 2K illustrates the recent development of various color light emitting films. Commission International de l'eclairage 1931 (CIE 1931) adjusted (x,y) values are summarized in Table 5 below.

TABLE 5
Comparison of CIE 1931 coordinates, operating performance and color purity

| | Turn-on | | CIE 1931 | Maximum | | Operating | | CIE 1931 | |
|---|---|---|---|---|---|---|---|---|---|
| Light | voltage | | Coordinates | luminance | | voltage at | | Coordinates at | |
| Color | (V [symbol] ) | | at V [symbol] | ( [symbol] ) | | [symbol] | | [symbol] | [Ref.] |
| Red | 2.82 | V | (0.60, 0.37) | 4 [symbol] 061 | cd/m² | 10.5 | V | (0.64, 0,36) | |
| Green | 2.65 | V | (0.28, 0.54) | 2 [symbol] 418 | cd/m² | 10.5 | V | (0.28, 0. [symbol] 6) | This work |
| Blue | 3.71 | V | (0.25, 0.28) | 5 [symbol] 823 | cd/m² | 9.5 | V | (0.29, 0.38) | |
| Blue | [symbol] 6.4 | V | n/a | 117 | cd/m² | 11.5 | V | (0.15, 0.06) | [24] |
| Blue | 2 | V | n/a | [symbol] 70 | cd/m² | 10 | V | n/a | [25] |
| Blue | [symbol] 10 | V | n/a | 331 | cd/m² | 19 | V | n/a | [26] |
| Blue | 9.3 | V | n/a | 3 [symbol] 274 | cd/m² | 28.5 | V | (0.15, 0.12) | [27] |
| Red | [symbol] 3 | V | n/a | [symbol] 7 [symbol] 100 | cd/m² | 9.5 | V | n/a | [28] |
| Green | [symbol] 4.5 | V | n/a | [symbol] 3 [symbol] 200 | cd/m² | 12 | V | n/a | [28] |
| Blue | [symbol] 4.5 | V | n/a | [symbol] 1 [symbol] 900 | cd/m² | 7. [symbol] | V | n/a | [28] |

[symbol]

Turn-on voltage at [symbol] cd/m² luminance [symbol] Maximum luminance value, ( [symbol] ) [symbol] approximate value [symbol] n/a [symbol] not applicable [symbol]
indicates data missing or illegible when filed

### [Experimental Example 13] Evaluation of Stretchability of Light Emitting Mixed Film

To systematically evaluate the stretchability of the RGB mixed film in PLED, a PLED device was manufactured using a transfer-printing method. The selectively stretched mixed film on the polydimethylsiloxane (PDMS) stamp was transferred to a rigid PLED substrate at various strain conditions to distinguish it from the strain effect of other layers.

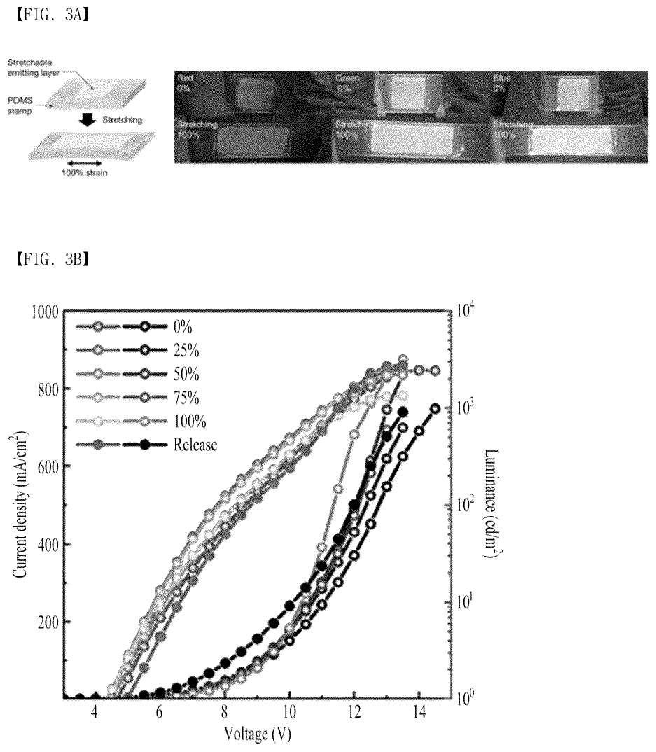

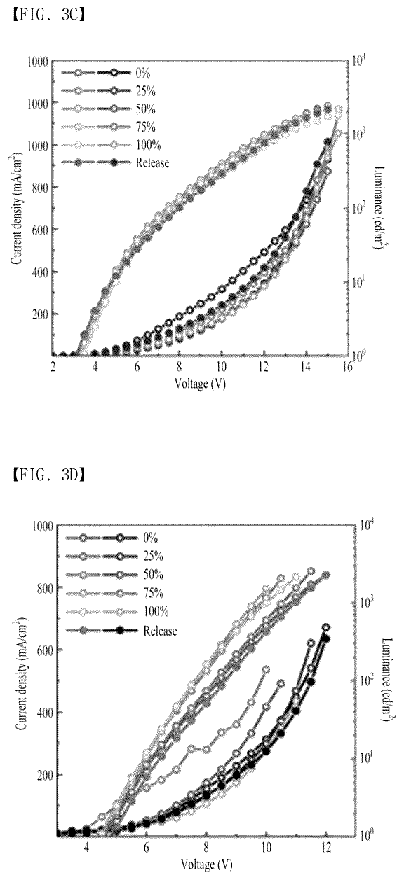

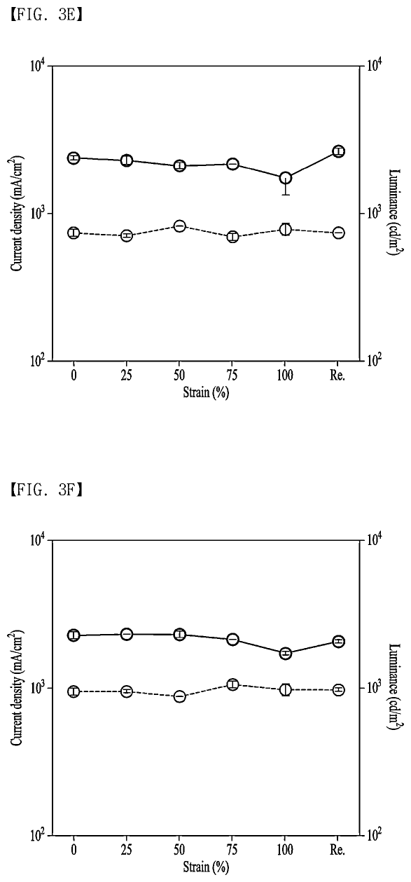

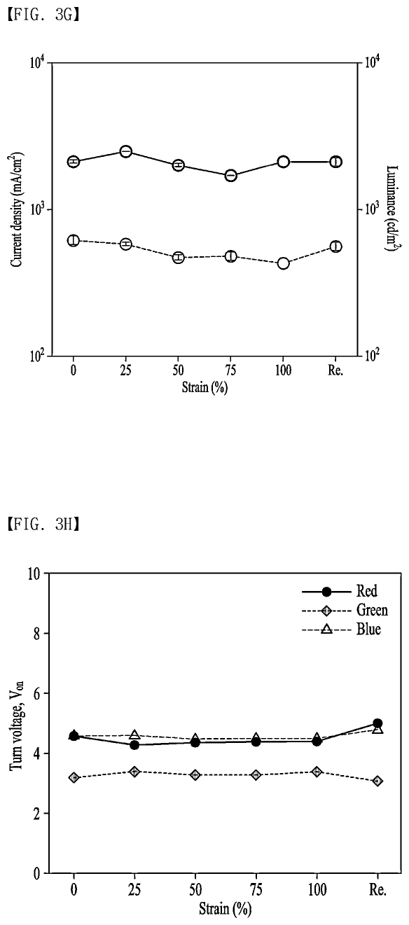

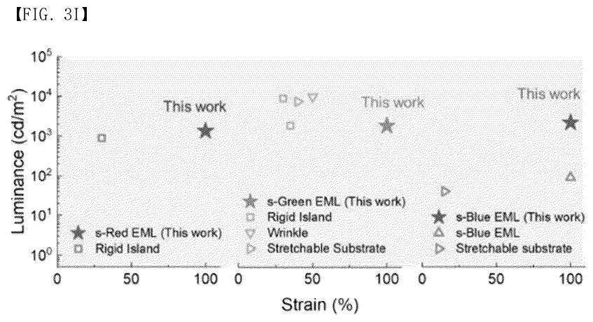

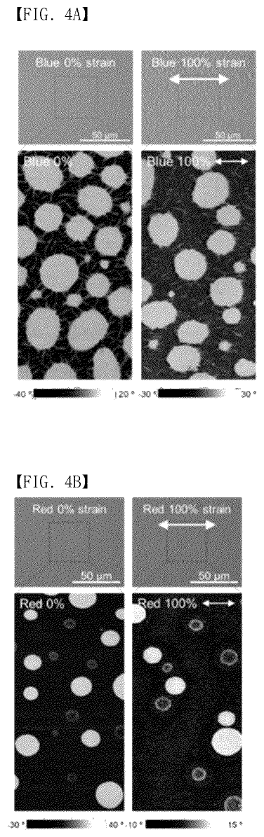

FIG. 3A illustrates the real-time PL spectra of 100% stretched RGB mixed films (the films of Examples 7-4, 8-5, and 9-4) on a PDMS stamp under 365 nm ultraviolet (UV) light. Each film clearly emitted RGB colors even at 100% strain without mechanical damage. In addition, the EL performance of the mixed films stretched at various strain conditions in the PLED device was evaluated.

FIGS. 3B to 3D illustrate the J-V-L curves of three-primary-color PLEDs (Examples 7-4, 8-5, and 9-4) with the mixed films stretched at various strain conditions (0, 25, 50, 75 and 100%). The RGB light emitting films have a similar thickness range (approximately 70 nm) and, accordingly, luminance characteristics are less dependent on film thickness. In particular, each RGB PLED showed almost the same J-V-L curve up to the maximum 100% strain without significant electrical deterioration even after strain recovery (release). The RGB PLED has high initial luminance (>103 cd/m²) and values were maintained in the same order from a low turn-on voltage (less than 5 Von) to a maximum 100% strain.

FIGS. 3E to 3G illustrate a graph showing the current density and luminance values of the red, green and blue PLED devices (Examples 7-4, 8-5, and 9-4) when strain is applied, and FIG. 3H illustrates the turn-on voltage (Von) under various strain conditions.

In the present disclosure, the light emitting performance may be maintained very stable under strain due to the nanodomains-based phase separation of the light emitting mixed film. Isotropic light emitting polymer nanodomains are not affected by strain because they are supported by the continuous dichroic ratio of the mixed film regardless of strain. In addition, In addition, in SEBS elastomers, nanowebs or intermixed networks at the molecular level of a light emitting polymer can efficiently interconnect light emitting nanodomains upon strain, which helps transport vertical and parallel charges. In addition, the low Von has the advantage of low power consumption when applied to wearable display applications (electrons skin and medical fields) along with long-term electrical stability

A transfer-printed light emitting film exhibits relatively lower luminance than a spin-coated film on a device substrate due to unavoidable mechanical damage during the film transfer process. Nevertheless, the luminance of the light emitting film according to the present disclosure showed the highest brightness value among the stretchable RGB light emitting films under 100% strain reported so far, as shown in FIG. 3I. FIG. 3I is a graph for comparing previously reported results and the performance of the stretchability of three-primary-color PLED device (red, green, blue from the left) obtained under various strain conditions.

A flexible PLED was additionally fabricated using an intrinsically stretchable EML film, and its EL performance was almost identical to that of a PLED fabricated on an ITO/glass rigid substrate. In addition, the flexible PLED can be integrated with a human finger and showed stable operation during bending-release movements.

### [Experimental Example 14] Evaluation of Luminous Properties of Light Emitting Mixed Film

In the mixed films according to the present disclosure, the strain states of the stretchable RGB films were measured at the micro and nano levels using optical microscopy (OM) and AFM analysis equipment to analyze the cause of the highly stable light emitting performance under strain.

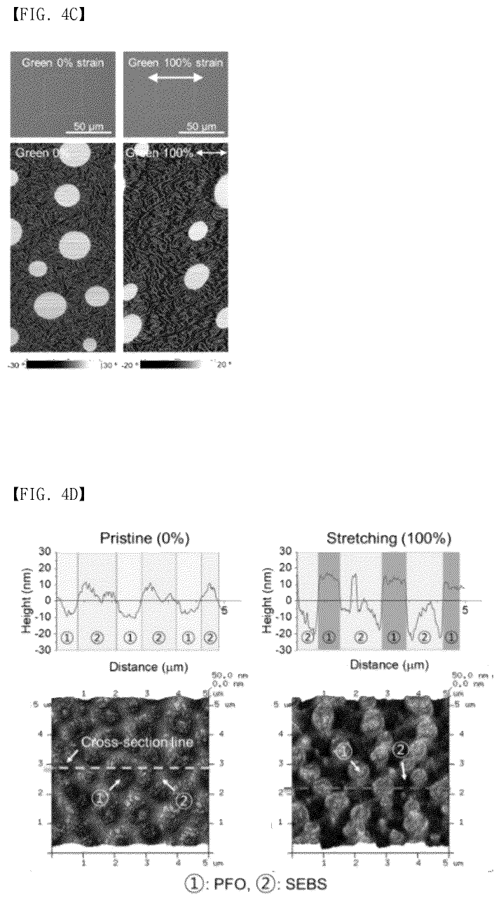

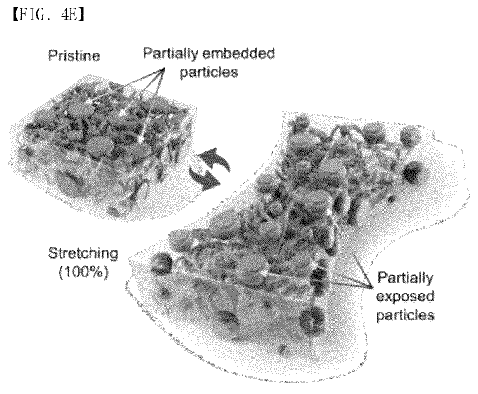

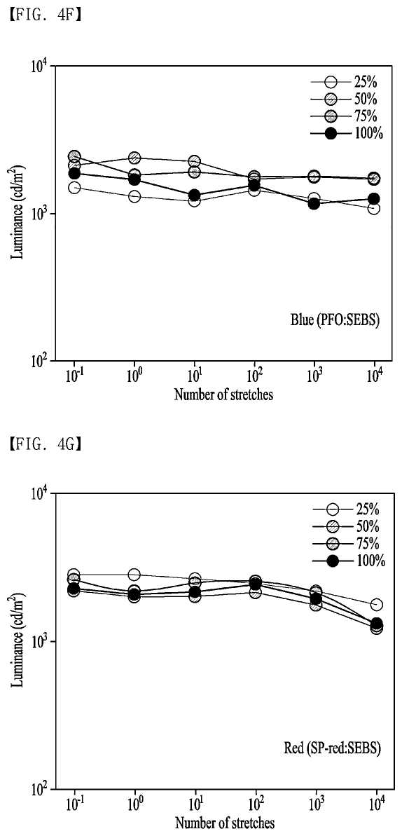

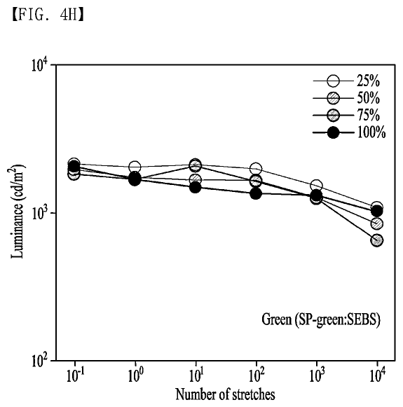

FIGS. 4A to 4C illustrate optical microscopy (OM) images (top) and AFM phase images (bottom) at 0 and 100% strain for Examples 1-4, 2-5, and 3-4, respectively. The average distance between nanodomains broadened linearly with the degree of stretching.

The nanodomain-based phase separation of all mixed films efficiently released the applied strain by stretching the elastic SEBS elastomer instead of the luminescent domain, efficiently preserving the shapes of the nanoweb and interconnected luminescent nanodomains in the SEBS elastomer. Accordingly, this results in the formation of an elastic luminescent mixed film that is resistant to strain.

### [Experimental Example 15] Morphological Analysis Related to Strain Mechanism of Light Emitting Mixed Film

To directly observe the energy dissipation mechanism under strain, the 3D morphology of the PFO:SEBS mixed film was measured through AFM. FIG. 4D illustrates the 3D height AFM images of the film at 0% strain (pristine) and 100% stretching for Example 3-4. (1) and (2 refer to the PFO and SEBS phases, respectively. The partially incorporated PFO nanodomains were progressively exposed to up to 100% strain without morphological damage, consistent with the proposed energy dissipation mechanism. This mechanism is generally applied to a SP-red and SP-green mixed film.

FIG. 4E illustrates the optical, electrical and morphological result resulting from the stretching of a light emitting mixed film according to the energy dissipation mechanism.

The RGB light emitting mixed film has excellent durability even after going through several stretching cycles. FIGS. 4F to 4H illustrate the luminances of Examples 4-4, 5-5 and 6-4 after stretching the solid substrate up to 10,000 times. Referring to FIGS. 4F to 4H, All the RGB PLED devices exhibited a luminance of 1,000 cd/m² or more during 1,000 multiple stretching cycles at 25, 50, 75 and 100% strain and were operated up to 10,000 cycles in all strain ranges without mechanical damage, demonstrating that these mixed films have the highest mechanical durability compared to previously reported results.

Finally, this elastic RGB mixed film can be biaxially stretched up to 30% while maintaining a luminance of more than 1,000 cd/m², which makes it possible to fabricate a skin-like biaxially stretched elastic luminescent film for PLEDs.

According to the present disclosure, an intrinsically stretchable PLED device can be fabricated by mixing a light emitting conjugated polymer and a non-polar elastomer. These three materials enable the fabrication of highly stretchable and robust primary color-emitting films.

The principle of this mixed system is as follows. The mixed system is a hybrid network of nanodomains and nanowebs and has multidimensional phase separation, enabling isotropic charges to be transported regardless of strain. Accordingly, efficient transport of charges is possible without photoelectric deterioration, and the charges can be recombined, making it possible to produce high luminance stretchable PLED.

The three-primary-color (Red, Green, Blue) mixed film can exhibit a high luminance value exceeding 1,000 cd/m² up to 100% strain at low Von of less than 5V. This luminance can be sustained for 10,000 multiple stretching cycles. That is, the mixed system can achieve the highest reported RGB luminance in a strained state along with mechanical durability. The stretchable light emitting mixed film having these characteristics can be effectively applied to displays with stretchability such as skin.

According to an embodiment of the present disclosure, a light emitting polymer and an elastomer can be phase-separated to a desired degree by mixing a light emitting polymer and an elastomer in a specific weight ratio.

According to an embodiment of the present disclosure, in a stretchable light emitting mixed composition, the spherical nanodomains of the light emitting polymer can be connected to each other due to one-dimensional (1D) nanowebs and molecular networks of the light emitting polymer. The nanodomain and nanoweb hybrid network can have a multidimensional phase-separated morphological structure. This structure enables isotropic charge transport regardless of the strain of a film containing the stretchable light emitting mixed composition, enabling efficient charge transport and recombination of charges without photoelectric deterioration. Therefore, a PLED device containing the stretchable light emitting mixed film can efficiently recombine electrons and holes injected from an electrode without mechanical damage up to a maximum of 100% strain. Accordingly, the PLED device can display a high luminance of 1,000 cd/m² or more during 1,000 repeated stretching conditions under a 100% strain condition.

Although the present disclosure has been described through limited examples and figures, the present disclosure is not intended to be limited to the examples. Those skilled in the art will appreciate that various modifications, additions and substitutions are possible, without departing from the scope and spirit of the disclosure. Therefore, it should be understood that there is no intent to limit the disclosure to the embodiments disclosed, rather, the disclosure is to cover all modifications, equivalents, and alternatives falling within the spirit and scope of the disclosure as defined by the claims.

What is claimed is:

1. A stretchable light emitting mixed composition, comprising:
a light emitting polymer comprising one of a red light emitting polymer, a green light emitting polymer and a blue light emitting polymer;
an elastomer; and
a solvent,
wherein, in the stretchable light emitting mixed composition, the light emitting polymer is phase-separated from the elastomer into a plurality of nanodomains.

2. The stretchable light emitting mixed composition according to claim 1, wherein the light emitting polymer is phase-separated from the elastomer due to a difference between a surface energy of the light emitting polymer and a surface energy of the elastomer to form the plural nanodomains.

3. The stretchable light emitting mixed composition according to claim 1, wherein a degree of phase separation is adjusted depending upon a mixing ratio of the light emitting polymer to the elastomer.

4. The stretchable light emitting mixed composition according to claim 1, wherein the light emitting polymer is phase-separated into the plural nanodomains and the plural nanowebs depending upon a mixing ratio of the light emitting polymer to the elastomer, and
the plural nanodomains and the plural nanowebs are connected to each other.

5. The stretchable light emitting mixed composition according to claim 1, wherein the red light emitting polymer and the elastomer are mixed in a weight ratio of 9:1 to 1:9.

6. The stretchable light emitting mixed composition according to claim 1, wherein the green light emitting polymer and the elastomer are mixed in a weight ratio of 9:1 to 1:9.

7. The stretchable light emitting mixed composition according to claim 1, wherein the blue light emitting polymer and the elastomer are mixed in a weight ratio of 9:1 to 1:9.

8. The stretchable light emitting mixed composition according to claim 1, wherein the light emitting polymer is nonpolar.

9. The stretchable light emitting mixed composition according to claim 1, wherein the elastomer is nonpolar.

10. The stretchable light emitting mixed composition according to claim 1, wherein the elastomer is one selected from the group consisting of a Styrene-Ethylene-Butylene-Styrene (SEBS) block copolymer, a Styrene-Butadiene-Styrene (SBS) block copolymer, a Styrene-Isoprene-Styrene (SIS) block copolymer, a Styrene-Butadiene Rubber (SBR) block copolymer and a Styrene-Ethylene-Propylene-Styrene (SEPS) block copolymer.

11. The stretchable light emitting mixed composition according to claim 1, wherein the light emitting polymer has a conjugation structure.

12. The stretchable light emitting mixed composition according to claim 1, wherein the red light emitting polymer is a red-light emitting spiro-copolymer or a PPV-based copolymer.

13. The stretchable light emitting mixed composition according to claim 1, wherein the green light emitting polymer is a green-light emitting spiro-copolymer.

14. The stretchable light emitting mixed composition according to claim 1, wherein the blue light emitting polymer is poly(9,9-di-n-octylfluorenyl-2,7-diyl) (PFO) or a polyfluorene copolymer.

15. A stretchable light emitting mixed film prepared using the stretchable light emitting mixed composition according to claim 1,
wherein, in the stretchable light emitting mixed composition, the light emitting polymer is phase-separated from the elastomer into a plurality of nanodomains.

16. The stretchable light emitting mixed film according to claim 15, wherein when the stretchable light emitting mixed film is strained, a structure of the light emitting polymer is preserved and the elastomer is deformed.

17. The stretchable light emitting mixed film according to claim 15, wherein the stretchable light emitting mixed film has a thickness of 50 nm to 130 nm.

18. A stretchable polymer light emitting diode (PLED) device, comprising:
a hole injection layer (HTL) formed on a lower electrode;
an emitting layer (EML) formed on the hole injection layer and comprising the stretchable light emitting mixed film according to claim 12;
an electron transport layer (ETL) formed on the light emitting layer; and
an upper electrode formed on the electron transport layer.

19. The stretchable PLED device according to claim 18, wherein, in the stretchable light emitting mixed film, the light emitting polymer is phase-separated into the plural nanodomains and the plural nanowebs depending upon a mixing ratio of the light emitting polymer and the elastomer, and
the plural nanodomains and the plural nanowebs are connected to each other to enable isotropic transport of charges.

20. The stretchable PLED device according to claim 19, wherein the plural nanodomains and the plural nanowebs are connected to each other so that charges recombine even when the stretchable polymer light emitting diode device is strained at 100% strain.
